(19) United States
(12) Patent Application Publication
(10) Pub. No.: US 2024/0324351 A1
(43) Pub. Date: Sep. 26, 2024

(54) DISPLAY APPARATUS

(71) Applicant: Samsung Display Co., Ltd., Yongin-si (KR)

(72) Inventors: Donghee Shin, Yongin-si (KR); Sunkwun Son, Yongin-si (KR)

(73) Assignee: Samsung Display Co., Ltd., Yongin-si (KR)

(21) Appl. No.: 18/545,058

(22) Filed: Dec. 19, 2023

(30) Foreign Application Priority Data
Mar. 24, 2023 (KR) 10-2023-0039083
May 4, 2023 (KR) 10-2023-0058491

(51) Int. Cl. H10K 59/131; H10K 59/121; H10K 59/126

(52) U.S. Cl. CPC H10K 59/131; H10K 59/1213; H10K 59/1216; H10K 59/126

(57) ABSTRACT

A display apparatus includes a scan line, a data line, a first active layer intersecting a portion of the scan line and having a first portion disposed in a direction to the data line and electrically connected to the data line, and a shield overlapping a portion of the first active layer, the portion of the first active layer overlapping the scan line.

### CROSS-REFERENCE TO RELATED APPLICATION(S)

This application claims priority to and benefits of Korean Patent Application No. 10-2023-0039083 under 35 U.S.C. § 119, filed on Mar. 24, 2023, and Korean Patent Application No. 10-2023-0058491, filed on May 4, 2023, in the Korean Intellectual Property Office, the entire contents of which are incorporated herein by reference.

### BACKGROUND

### 1. Technical Field

One or more embodiments relate to display apparatuses, and more, to a display apparatus capable of displaying a high-quality image.

### 2. Description of the Related Art

Generally, in a display apparatus such as an organic light-emitting display apparatus, thin-film transistors, connection electrodes, and wiring are arranged in each (sub)pixel to control the luminance or the like of each (sub)pixel. The thin-film transistors, the connection electrodes, and the wiring form a multi-layered structure.

A conventional display apparatus has a problem in that the luminance of some pixels may be unintentionally changed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus capable of displaying a high-quality image. However, aspects of embodiments are not limited thereto, and the above characteristics do not limit the scope of embodiments according to the disclosure.

Additional aspects will be set forth in part in the description which follows and, in part, will be apparent from the description, or may be learned by practice of the embodiments of the disclosure.

According to one or more embodiments, a display apparatus may include a scan line; a data line; a first active layer intersecting a portion of the scan line and having a first portion disposed in a direction to the data line and electrically connected to the data line; and a shield overlapping a portion of the first active layer, the portion of the first active layer overlapping the scan line.

The display apparatus may further include a data connection line electrically connecting the first portion of the first active layer to the data line.

The scan line and the data connection line may be disposed on a same layer.

The first active layer may be disposed below the scan line.

The shield may be disposed below the first active layer.

The data line and the shield may be disposed on a same layer.

The scan line may extend in a first direction and have a protrusion protruding in a second direction intersecting the first direction, the first active layer may extend in the first direction to intersect the protrusion, and the first portion may be disposed in a direction to the data line with respect to the protrusion of the scan line.

The data line may be disposed on a side of the protrusion of the scan line and extend in the second direction.

The shield may overlap the protrusion of the scan line.

The shield may extend along the protrusion of the scan line.

The shield may be disposed over a substrate and the protrusion of the scan line may be disposed in the shield as viewed in a direction perpendicular to the substrate.

The display apparatus may further include a driving gate electrode electrically connected to a second portion of the first active layer disposed in a direction away from the data line with respect to the protrusion of the scan line.

The scan line may extend in a first direction, the display apparatus may further include a horizontal common voltage line extending in the first direction, and the shield may be electrically connected to the horizontal common voltage line.

The horizontal common voltage line and the scan line may be disposed on a same layer.

For a first pixel and a second pixel adjacent to each other in a second direction with respect to the horizontal common voltage line, the second direction intersecting the first direction, a shield of the first pixel and a shield of the second pixel may be formed as a single body.

The display apparatus may further include a common electrode formed as a single body to correspond to a plurality of pixels, and the common electrode may be electrically connected to the horizontal common voltage line.

The scan line may extend in a first direction, the display apparatus may further include a horizontal power line extending in the first direction, and the shield may be electrically connected to the horizontal power line.

The horizontal power line and the scan line may be disposed on a same layer.

For a first pixel and a second pixel adjacent to each other in the second direction with respect to the horizontal power line, the second direction intersecting the first direction, a shield of the first pixel and a shield of the second pixel may be formed as a single body.

The scan line may have a protrusion protruding in a second direction intersecting the first direction, the first active layer may extend in the first direction to intersect the protrusion of the scan line, and the first portion may be disposed in a direction to the data line with respect to the protrusion of the scan line. The display apparatus may further include a driving gate electrode electrically connected to a second portion of the first active layer disposed in a direction away from the data line with respect to the protrusion of the scan line, a second active layer intersecting the driving gate electrode and the first active layer being disposed on a same layer, and a vertical power line electrically connected to the second active layer and extending in the first direction. The horizontal power line may be electrically connected to the vertical power line.

These and/or other aspects will become apparent and more readily appreciated from the following description of the embodiments, the claims, and the accompanying drawings.

### BRIEF DESCRIPTION OF THE DRAWINGS

The above and other aspects, features, and advantages of the disclosure will be more apparent from the following description taken in conjunction with the accompanying drawings, in which:

FIG. 1 is a schematic plan view of a portion of a display apparatus according to an embodiment;

FIG. 2 is a schematic diagram of a portion of the display apparatus of FIG. 1;

FIG. 3 is a schematic diagram of an equivalent circuit illustrating a display device included in the display apparatus of FIG. 1 and a pixel circuit connected to the display device;

FIG. 4 is a schematic plan diagram illustrating locations of transistors and a storage capacitor in one pixel included in the display apparatus of FIG. 1;

FIGS. 5 through 8 are schematic plan diagrams illustrating, on a layer-by-layer basis, components, such as transistors and a storage capacitor, of the display apparatus of FIG. 4;

FIG. 9 is a schematic cross-sectional view taken along line A-A′ of FIG. 4;

FIG. 10 is a schematic plan diagram illustrating respective locations of transistors and a storage capacitor in pixels included in a display apparatus according to an embodiment;

FIGS. 11 and 12 are schematic plan diagrams illustrating, on a layer-by-layer basis, components, such as transistors and a storage capacitor, of the display apparatus of FIG. 10;

FIG. 13 is a schematic plan diagram of one layer or a layer of pixels included in a display apparatus according to an embodiment;

FIG. 14 is a schematic plan diagram illustrating respective locations of transistors and a storage capacitor in pixels included in a display apparatus according to an embodiment;

FIGS. 15 and 16 are schematic plan diagrams illustrating, on a layer-by-layer basis, components, such as transistors and a storage capacitor, of the display apparatus of FIG. 14; and

FIG. 17 is a schematic plan diagram of one layer or a layer of pixels included in a display apparatus according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b or c” indicates only a, only b, only c, both a and b, both a and c, both b and c, all of a, b, and c, or variations thereof.

As the disclosure allows for various changes and numerous embodiments, embodiments will be illustrated in the drawings and described in detail in the written description. Hereinafter, effects and features of the disclosure and a method for accomplishing them will be described more fully with reference to the accompanying drawings, in which embodiments are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that, unless otherwise specified, when an element such as a layer, film, region or substrate is referred to as being “on” another element, it can be “directly” on the other element or intervening elements may also be present. In the drawings, the thicknesses of layers and regions are exaggerated or reduced for convenience of explanation. For example, since sizes and thicknesses of components in the drawings are arbitrarily illustrated for convenience of explanation, embodiments are not limited thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

It will be understood that although the terms “first,” “second,” etc. may be used herein to describe various components, these components should not be limited by these terms. These components are only used to distinguish one component from another. For example, a first element may be referred to as a second element, and similarly, a second element may be referred to as a first element without departing from the scope of the disclosure.

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will also be understood that when a layer, region, or component is referred to as being “connected” or “coupled” to another layer, region, or component, it can be directly connected or coupled to the other layer, region, or component or intervening layers, regions, or components may be present. For example, when a layer, region, or component is referred to as being “electrically connected” or “electrically coupled” to another layer, region, or component, it can be directly electrically connected or coupled to the other layer, region, or component or intervening layers, regions, or components may be present.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

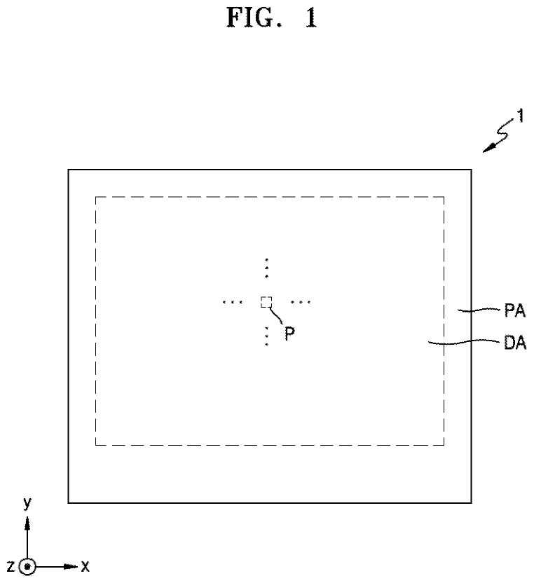

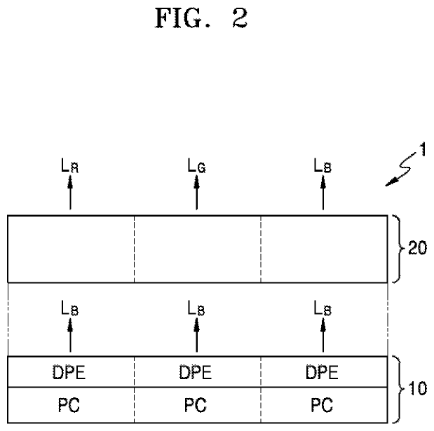

FIG. 1 is a schematic plan view of a portion of a display apparatus 1 according to an embodiment, and FIG. 2 is a schematic diagram of a portion of the display apparatus 1 of FIG. 1.

As shown in FIG. 1, the display apparatus 1 may include a display area DA in which a plurality of pixels P are arranged, and a peripheral area PA located (or disposed) outside of the display area DA. The peripheral area PA may entirely surround the display area DA or may be adjacent to the display area DA.

The display area DA may have the shape of a polygon including a quadrangle, as shown in FIG. 1. For example, the display area DA may have a rectangular shape in which a horizontal length is greater than a vertical length, a rectangular shape in which a horizontal length is less than a vertical length, or a square shape. By way of example, the display area DA may have any of various shapes such as a polygonal shape other than a rectangle, an oval, or a circle. It is to be understood that the shapes disclosed herein include shapes substantial to the shapes disclosed herein.

As shown in FIG. 2, the display apparatus 1 may include a light-emitting panel 10 and a filter panel 20 stacked each other. The light-emitting panel 10 may include a plurality of display devices DPE, and each of the display devices DPE is electrically connected to a circuit PC (hereinafter, referred to as a pixel circuit PC) corresponding thereto. The display devices DPE and the pixel circuits PC may be arranged in the display area DA.

The display area DA may provide an image by using light of the display devices DPE. For example, blue light L_{B} emitted by the display devices DPE may be converted into red light L_{R} and green light L_{G} while passing through the filter panel 20, or may pass through the filter panel 20 without being converted. The display apparatus 1 may provide an image by using light converted by the filter panel 20 or transmitted by the filter panel 20 without being converted, for example, the red light L_{R}, the green light L_{G}, and the blue light L_{B}.

The peripheral area PA is a non-display area that provides no images, and may surround the entirety of the display area DA. A driver or a main power line for providing an electrical signal or power to the pixel circuits PC may be arranged in the peripheral area PA. The peripheral area PA may include a pad to which an electronic device or a printed circuit board (PCB) may be electrically connected.

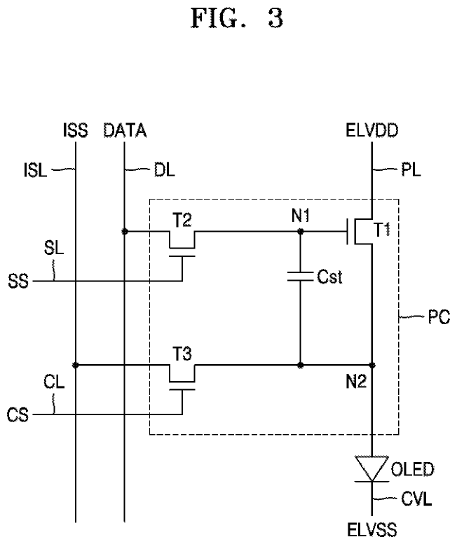

FIG. 3 is a schematic diagram of an equivalent circuit illustrating a display device DPE included in the display apparatus 1 and a pixel circuit PC connected to the display device DPE. In FIG. 3, an organic light-emitting diode OLED, which is the display device DPE, is electrically connected to the pixel circuit PC. In detail, a pixel electrode of the organic light-emitting diode OLED may be electrically connected to the pixel circuit PC, and an opposite electrode of the organic light-emitting diode OLED may be electrically connected to a common voltage line CVL providing a common power supply voltage ELVSS. The organic light-emitting diode OLED may emit light with a brightness corresponding to a current amount provided by the pixel circuit PC.

The pixel circuit PC may include a first transistor T1, a second transistor T2, a third transistor T3, and a storage capacitor Cst. Each of the first transistor T1, the second transistor T2, and the third transistor T3 may be an oxide semiconductor thin-film transistor including a semiconductor layer formed of an oxide semiconductor, or may be a silicon semiconductor thin-film transistor including a semiconductor layer formed of polysilicon.

The first transistor T1 may be a driving transistor. One end or an end of the first transistor T1 may be electrically connected to the pixel electrode of the organic light-emitting diode OLED, and another end of the first transistor T1 may be electrically connected to a power line PL that supplies a driving power supply voltage ELVDD. A driving gate electrode of the first transistor T1 may be electrically connected to a first node N1. The first transistor T1 may control a current amount flowing from the power line PL to the organic light-emitting diode OLED in accordance with a voltage of the first node N1.

The second transistor T2 may be a switching transistor. One end or an end of the second transistor T2 may be electrically connected to a data line DL, and another end of the second transistor T2 may be electrically connected to the first node N1. A switching gate electrode of the second transistor T2 may be electrically connected to a scan line SL. The second transistor T2 may be turned on in case that a scan signal SS is supplied to the scan line SL, and may electrically connect the data line DL to the first node NI to transmit a data signal DATA from the data line DL to the first node N1.

The third transistor T3 may be an initialization-sensing transistor. One end or an end of the third transistor T3 may be electrically connected to an initialization-sensing line ISL, and another end of the third transistor T3 may be electrically connected to a second node N2. An initialization gate electrode of the third transistor T3 may be electrically connected to a control line CL.

The third transistor T3 may be turned on in case that a control signal CS is supplied to the control line CL, and may electrically connect the initialization-sensing line ISL to the second node N2 to transmit an initialization-sensing signal ISS from the initialization-sensing line ISL to the second node N2. For example, in case that the third transistor T3 is turned on, the third transistor T3 may initialize the potential of a pixel electrode of the organic light-emitting diode OLED by using the initialization-sensing signal ISS from the initialization-sensing line ISL as an initialization voltage. By way of example, in case that the third transistor T3 is turned on, the third transistor T3 may sense property information of the organic light-emitting diode OLED. As such, the third transistor T3 may include both a function as an initialization transistor as described above and a function as a sensing transistor as described above, or may include one of the two functions. In case that the third transistor T3 may include the function as the initialization transistor, the initialization-sensing line ISL may be considered as an initializing voltage line, and, in case that the third transistor T3 may include the function as the sensing transistor, the initialization-sensing line ISL may be considered as a sensing line. An initialization operation and a sensing operation of the third transistor T3 may be individually conducted or may be simultaneously conducted. In other words, the third transistor T3 may be an initialization transistor and/or a sensing transistor. For convenience of description, a case where the third transistor T3 has both the function of the initialization transistor and the function of the sensing transistor will now be focused on and described in detail.

The storage capacitor Cst may be connected between the first node N1 and the second node N2. For example, one capacitor electrode of the storage capacitor Cst may be electrically connected to the driving gate electrode of the first transistor T1, and the other capacitor electrode of the storage capacitor Cst may be electrically connected to the pixel electrode of the organic light-emitting diode OLED.

Although a case where the pixel circuit PC may include the three transistors T1 through T3 and the one storage capacitor Cst is illustrated in FIG. 3, the disclosure is not limited thereto. For example, the number of transistors or storage capacitors included in the pixel circuit PC may vary.

Although the display device DPE is the organic light-emitting diode OLED including an organic material in FIG. 3, embodiments are not limited thereto. For example, the display device DPE may be an inorganic light-emitting diode including an inorganic material. The inorganic light-emitting diode may include a PN diode including materials based on an inorganic material semiconductor. In case that a voltage is applied to the PN junction diode in a forward direction, holes and electrons are injected, and energy generated by recombination of the holes and the electrons is converted into light energy to thereby emit light of a given color. Such an inorganic light-emitting diode may have a width of several to several hundreds of micrometers. The inorganic light-emitting diode may be referred to as a micro LED.

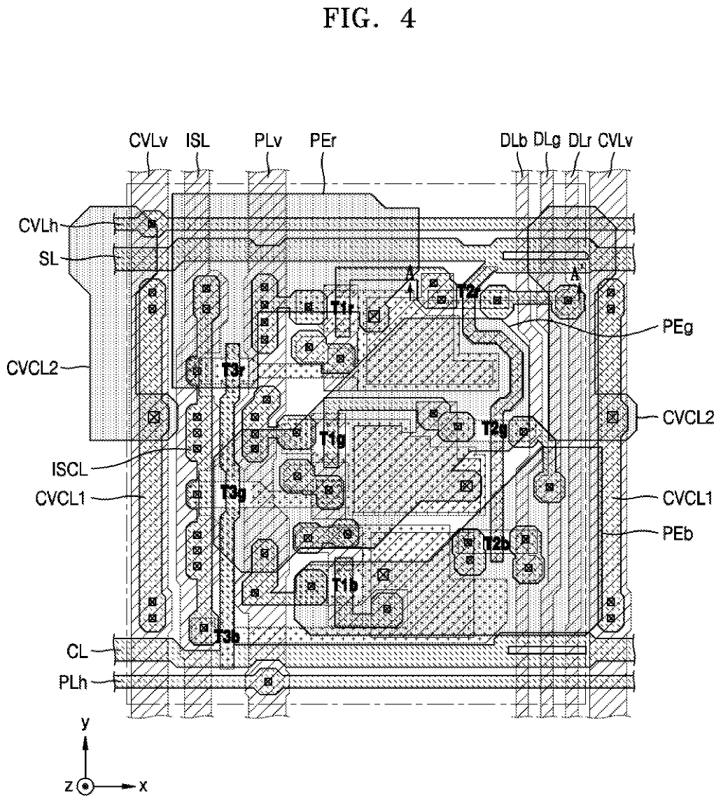

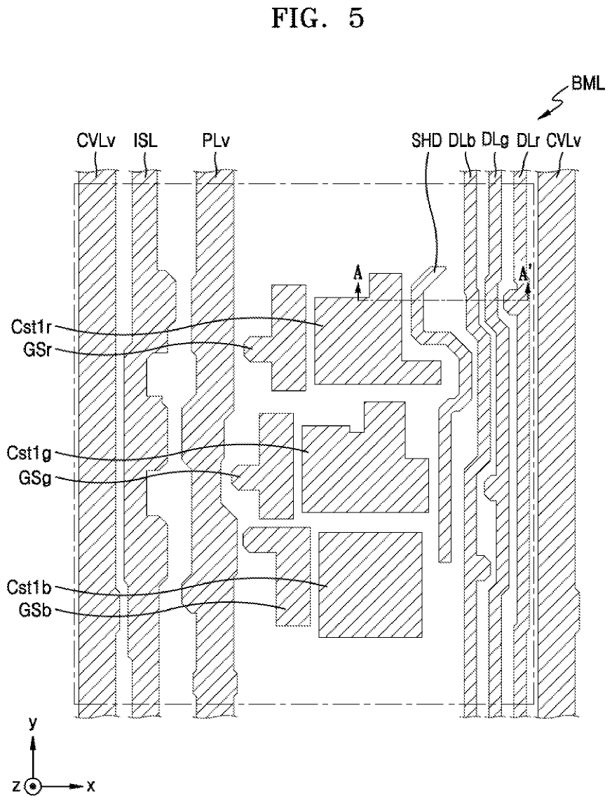

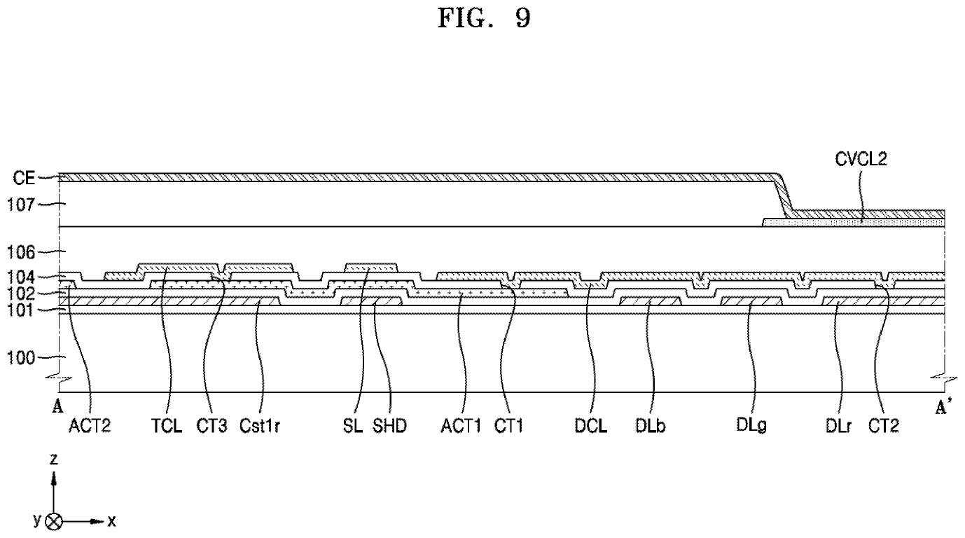

FIG. 4 is a plan diagram schematically illustrating locations of transistors and a storage capacitor Cst in one pixel included in the display apparatus 1 of FIG. 1, FIGS. 5 through 8 are plan views schematically illustrating, on a layer-by-layer basis, components such as the transistors and storage capacitor Cst of the display apparatus 1 of FIG. 4, and FIG. 9 is a schematic cross-sectional view taken along line A-A′ of FIG. 4. For reference, one pixel may include a plurality of sub-pixels, for example, three sub-pixels, and accordingly, the above-described equivalent circuit diagram of FIG. 3 is an equivalent circuit diagram of one sub-pixel. FIG. 4 schematically illustrates positions of transistors and storage capacitors Cst in one pixel including three subpixels.

As shown in these drawings, one pixel may include three sub-pixels. FIG. 4 illustrates a case in which one pixel may include a red subpixel, a green subpixel, and a blue subpixel. The red subpixel may include one storage capacitor Cst including a first capacitor electrode Cst1r (sec FIG. 5) and three transistors T1r, T2r, and T3r, the green subpixel may include one storage capacitor Cst including a first capacitor electrode Cst1g (see FIG. 5) and three transistors T1g, T2g, and T3g, and the blue subpixel may include one storage capacitor Cst including a first capacitor electrode Cst1b (see FIG. 5) and three transistors T1b, T2b, and T3b. Components of the green subpixel and components of the blue subpixel are identical to and/or similar to components of the red subpixel. Accordingly, for convenience of description, the components of the red subpixel will now be focused on and described. This description is equally applicable to the components of the green subpixel and the components of the blue subpixel.

The display apparatus 1 may include a substrate 100 (see FIG. 9), and various components, such as the transistors T1r, T2r, and T3r and the storage capacitor Cst, may be positioned on the substrate 100. The substrate 100 may include glass, a metal, or a polymer resin. In case that the substrate 100 is flexible or bendable, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers cach including a polymer resin and a barrier layer including an inorganic material (silicon oxide, silicon nitride, silicon oxynitride, or the like) and located between the two layers. In this way, various modifications may be made.

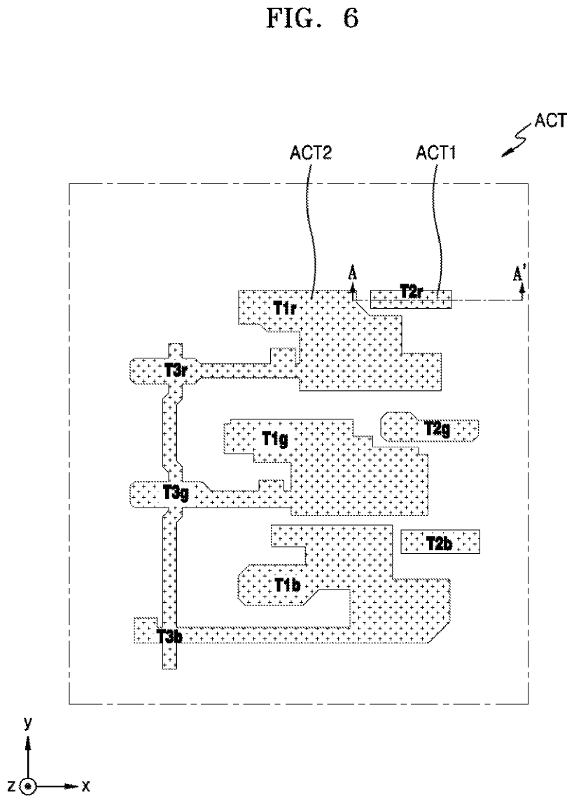

A first buffer layer 101 (see FIG. 9) including an inorganic insulating material, such as silicon oxide, silicon nitride, silicon oxynitride, or aluminum oxide, may be positioned on the substrate 100. The first buffer layer 101 may prevent metal atoms, impurities, or the like from the substrate 100 from being diffused into an active layer ACT (see FIG. 6) located thereover.

A bottom metal layer BML as shown in FIG. 5 may be disposed on the first buffer layer 101. The bottom metal layer BML may include various signal lines, and may serve to protect the active layer ACT located thereon by overlapping at least a portion of the active layer ACT. In case that the active layer ACT may include polysilicon, the bottom metal layer BML may control a heat supply rate during a crystallization process for forming the active layer ACT, such that the active layer ACT may be uniformly crystallized. The bottom metal layer BML may include a metal, an alloy, a conductive metal oxide, or a transparent conductive material, for example. For example, the bottom metal layer BML may include silver (Ag), an alloy containing silver, molybdenum (Mo), an alloy containing molybdenum, aluminum (Al), an alloy containing aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The bottom metal layer BML may have a multi-layered structure. For example, the bottom metal layer BML may have a double-layer structure of Mo/Al or Ti/Al or a three-layered structure of Ti/Al/Ti.

As shown in FIG. 5, the bottom metal layer BML may include a vertical common voltage line CVLv, an initialization-sensing line ISL, a vertical power line PLv, a blue data line DLb, a green data line DLg, a red data line DLr, first capacitor electrodes Cst1r, Cst1g, and Cst1b, driving gate electrode shields GSr, GSg, and GSb, and a shield SHD. The vertical common voltage line CVLv, the initialization-sensing line ISL, the vertical power line PLv, the blue data line DLb, the green data line DLg, and the red data line DLr may be sequentially arranged in a first direction (x-axis direction).

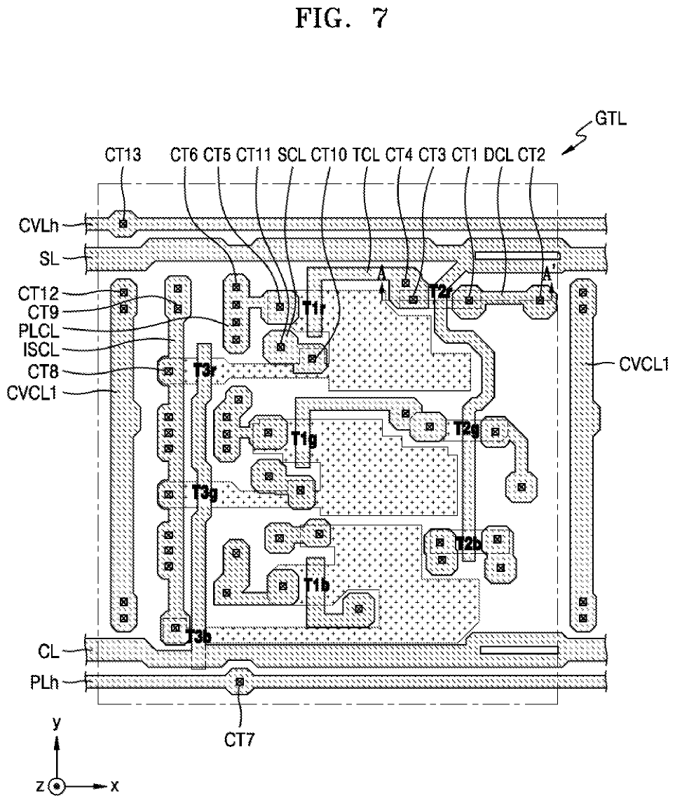

The vertical common voltage line CVLv may extend in a second direction (y-axis direction) intersecting the first direction (x-axis direction). The vertical common voltage line CVLv may be electrically connected to a horizontal common voltage line CVLh (refer to FIG. 7) extending in the first direction (x-axis direction), which will be described later. Accordingly, the common voltage line CVL including the vertical common voltage line CVLv and the horizontal common voltage line CVLh electrically connected to each other may have a substantially lattice shape in the display area DA, and thus may have a potential corresponding to the common power supply voltage ELVSS that is substantially uniform in the display area DA. The common voltage line CVL may be electrically connected to a common electrode CE (see FIG. 9), which is an upper electrode of the organic light-emitting diode, so that the common electrode CE has a uniform potential in the display area DA.

The initialization-sensing line ISL may extend in the second direction (y-axis direction). The initialization-sensing line ISL may be electrically connected to a first portion of each of the third transistors T3r, T3g, and T3b, which are initialization-sensing transistors, so that, in case that the third transistors T3r, T3g, and T3b are turned on, the initialization-sensing signal ISS from the initialization-sensing line ISL may be transmitted to a red pixel electrode PEr, a green pixel electrode PEg, or a blue pixel electrode PEb.

The vertical power line PLv may extend in the second direction (y-axis direction) intersecting the first direction (x-axis direction). The vertical power line PLv may be electrically connected to a horizontal power line PLh (see FIG. 7) extending in the first direction (x-axis direction), which will be described later. Accordingly, the power line PL including the vertical power line PLv and the horizontal power line PLh electrically connected to each other may have a substantially lattice shape in the display area DA, and thus may have a potential of the power supply voltage ELVDD that is substantially uniform in the display area DA. The power line PL may be electrically connected to each of the first transistors T1r, T1g, and T1b, which are driving transistors, and may serve to apply the power supply voltage ELVDD to the first transistors T1r, T1g, and T1b.

Each of the blue data line DLb, the green data line DLg, and the red data line DLr may extend in the second direction (y-axis direction). The red data line DLr is electrically connected to a first portion of the second transistor T2r of the red subpixel, the green data line DLg is electrically connected to a first portion of the second transistor T2g of the green subpixel, and the blue data line DLb is electrically connected to a first portion of the second transistor T2b of the blue subpixel. In case that the second transistor T2r of the red subpixel, the second transistor T2g of the green subpixel, and the second transistor T2b of the blue subpixel are turned on by the scan line SL (see FIG. 7), the second transistor T2r of the red subpixel, the second transistor T2g of the green subpixel, and the second transistor T2b of the blue subpixel may transmit the data signal DATA from the red data line DLr, the green data line DLg, and the blue data line DLb to a driving gate electrode of the first transistor T1r of the red subpixel, a driving gate electrode of the first transistor T1g of the green subpixel, and a driving gate electrode of the first transistor T1b of the blue subpixel.

The first capacitor electrodes Cst1r, Cst1g, and Cst1b, the driving gate electrode shields GSr, GSg, and GSb, and the shield SHD may be positioned between a set of the vertical common voltage line CVLv, the initialization-sensing line ISL, and the vertical power supply PL and a set of the blue data line DLb, the green data line DLg, and the red data line DLr. When viewed in a direction perpendicular to the substrate 100 (z-axis direction), cach of the first capacitor electrodes Cst1r, Cst1g, and Cst1b and each of the driving gate electrode shields GSr, GSg, and GSb may have isolated shapes. The shield SHD may have a shape substantially extending in the second direction (y-axis direction). The selected shape and function of the shield SHD will be described later.

Each of the first capacitor electrodes Cst1r, Cst1g, and Cstb may be one capacitor electrode of the storage capacitor Cst. Each of the driving gate electrode shields GSr, GSg, and GSb may overlap at least a portion of a corresponding transistor connection line among transistor connection lines TCL (see FIG. 7), which may be considered driving gate electrodes, and thus may protect the active layer ACT located thereover.

A second buffer layer 102 (see FIG. 9) may be disposed on the first buffer layer 101 to cover the bottom metal layer BML. The second buffer layer 102 may include an insulating material. For example, the second buffer layer 102 may include an inorganic insulating material such as silicon oxide, silicon nitride, silicon oxynitride, or aluminum oxide.

The active layer ACT shown in FIG. 6 may be disposed over the second buffer layer 102. The active layer ACT may include polysilicon or may include an oxide semiconductor. The oxide semiconductor may include Zn oxide, In—Zn oxide, or Ga—In—Zn oxide, as a Zn oxide-based material. By way of example, the oxide semiconductor may include an In—Ga—Zn—O (IGZO), In—Sn—Zn—O (ITZO), or In—Ga—Sn—Zn—O (IGTZO) containing metals, such as In, Ga, and Sn, in ZnO. For convenience, a case in which the active layer ACT may include an oxide semiconductor will now be described.

The active layer ACT may include a first active layer ACT1 and a second active layer ACT2. The first active layer ACT1 of the red subpixel, the first active layer ACT1 of the green subpixel, and the first active layer ACT1 of the blue subpixel may be spaced apart from each other, whereas the second active layer ACT2 of the red subpixel, the second active layer ACT2 of the green subpixel, and the second active layer ACT2 of the blue subpixel may be connected to each other and may be formed as a single body.

Each of the first active layers ACTI may have a shape extending in the first direction (x-axis direction) to intersect a portion of the scan line SL. In other words, the first active layers ACTI may be components of the second transistors T2r, T2g, and T2b, which are switching transistors. A first portion of each of the first active layers ACTI located in the direction to the data lines DLr, DLg, and DLb may be electrically connected to a corresponding data line among the data lines DLr, DLg, and DLb.

Portions of the second active layer ACT2 may be components of the first transistors T1r, T1g, and T1b, which are driving transistors, may be components of the third transistors T3r, T3g, and T3b, which are initialization-sensing transistors, and may serve as second capacitor electrodes corresponding to the first capacitor electrodes Cst1r, Cst1g, and Cst1b of storage capacitors Cst. This will be described later.

A gate insulating layer 104 of FIG. 9 may be disposed on the second buffer layer 102 to cover the active layer ACT. The gate insulating layer 104 may include an insulating material. For example, the gate insulating layer 104 may include an inorganic insulating material such as silicon oxide, silicon nitride, silicon oxynitride, or aluminum oxide.

A gate layer GTL shown in FIG. 7 may be disposed on the gate insulating layer 104. For reference, for convenience of illustration, the gate layer GTL is illustrated together with the active layer ACT in FIG. 7.

The gate layer GTL may include a horizontal common voltage line CVLh, a scan line SL, a control line CL, and a horizontal power line PLh each extending in a substantially first direction (x-axis direction), a first common voltage connection line CVCL1 and an initialization-sensing connection line ISCL each extending in a substantially second direction (y-axis direction), and a data connection line DCL, a transistor connection line TCL, a power supply connection line PLCL, and a shield connection line SCL cach having an isolated shape. Each of the red subpixel, green subpixel, and blue subpixel may have the data connection line DCL, the transistor connection line TCL, the power connection line PLCL, and the shield connection line SCL. A configuration in the red subpixel will now be described representatively.

The gate layer GTL may include a metal, an alloy, a conductive metal oxide, or a transparent conductive material. For example, the gate layer GTL may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The gate layer GTL may have a multi-layered structure. For example, the gate layer GTL may have a double-layer structure of Mo/Al or Ti/Al or a three-layered structure of Ti/Al/Ti.

As described above, because the gate layer GTL and the active layer ACT are illustrated together in FIG. 7 for convenience, impurities may be added to a portion of the active layer ACT that does not overlap the gate layer GTL. In other words, the portion of the active layer ACT that does not overlap the gate layer GTL may be a doped portion. Accordingly, electrical characteristics of the portion of the active layer ACT that does not overlap the gate layer GTL may be different from those of a portion of the active layer ACT that overlaps the gate layer GTL. In detail, resistance of the portion of the active layer ACT that does not overlap the gate layer GTL may be lower than resistance of the portion of the active layer ACT overlapping the gate layer GTL in case that no channels are formed in the overlapping portion. Therefore, for example, in the red subpixel, a portion of the second active layer ACT2 overlapping the first capacitor electrode Cst1r may function as a conductor and become a second capacitor electrode. The portion of the active layer ACT not overlapping the gate layer GTL may be a source region or a drain region, and may also serve as wiring.

The scan line SL may extend substantially in the first direction (x-axis direction) and may have a protrusion protruding in the second direction (y-axis direction) intersecting the first direction. As described above, the first active layer ACT1 has a shape extending in the first direction (x-axis direction) to intersect a portion of the scan line SL, and, for example, may have a shape extending in the first direction (x-axis direction) so as to intersect the protrusion of the scan line SL.

As shown in FIGS. 4, 5, 7 and 9, the shield SHD as described above may overlap a portion of the first active layer ACT1 that overlaps the scan line SL. Furthermore, as shown in FIGS. 4, 5 and 7, the shield SHD may overlap the protrusion of the scan line SL. Accordingly, the shield SHD may extend along the protrusion of the scan line SL.

As described above, the portion of the active layer ACT not overlapping the gate layer GLT is doped and thus has low resistance, and accordingly may function like a conductive layer. Because a first portion of the first active layer ACT1 located in the direction to the red data line DLr with respect to the protrusion of the scan line SL is electrically connected to the red data line DLr, the potential of the first portion of the first active layer ACT1 becomes substantially the same as that of the red data line DLr. Similarly, because a second portion of the first active layer ACT1 located in a direction away from the red data line DLr with respect to the protrusion of the scan line SL is electrically connected to the transistor connection electrode TCL, namely, a driving gate electrode, the potential of the second portion of the first active layer ACT1 becomes substantially the same as that of the driving gate electrode.

In case that the second transistor T2r, which is a switching transistor, is turned off because no electrical signal is applied to the scan line SL of a corresponding pixel, the red data line DLr transmits data signal DATA that is to be applied to pixels located in different rows. Because the data signal DATA is a signal that varies according to an image to be realized, the data signal DATA transmitted by the red data line DLr continuously changes. Therefore, in case that the second transistor T2r, which is a switching transistor, is in a turn-off state, the potential of the first portion of the first active layer ACT1 continues to change, and the second portion of the first active layer ACT1 positioned adjacent thereto also continues to change. As described above, because the second portion of the first active layer ACT1 is electrically connected to the driving gate electrode, the potential of the driving gate electrode may be unintentionally changed, resulting in emission of unintended luminance light from the corresponding pixel. For example, in the case of a high-resolution display apparatus, as a distance between the first portion and the second portion of the first active layer ACT1 becomes closer, the possibility of occurrence of such a defect may increase.

However, in the case of the display apparatus according to an embodiment, the shield SHD overlaps the portion of the first active layer ACT1 overlapping the scan line SL. Therefore, an electrical influence of the first portion of the first active layer ACT1 upon the second portion thereof may be effectively prevented or minimized by the shield SHD located between the first portion and the second portion of the first active layer ACT1. Accordingly, a display apparatus capable of displaying high-quality images may be implemented.

The shield SHD may overlap the portion of the first active layer ACT1 overlapping the scan line SL. Furthermore, as shown in FIGS. 4, 5 and 7, the shield SHD may overlap the protrusion of the scan line SL. Accordingly, the shield SHD may extend along the protrusion of the scan line SL. If necessary, when viewed in a direction perpendicular to the substrate 100 (z-axis direction), the protrusion of the scan line SL is positioned within the shield SHD so that the influence of the first portion of the first active layer ACT1 upon the second portion thereof may be minimized. The shape modification of the shield SHD may also be applied to embodiments to be described later and their modifications.

The data connection line DCL may be electrically connected to the first portion of the first active layer ACT1 below the data connection line DCL through a first contact hole CT1, and may be electrically connected to the red data line DLr below the data connection line DCL through a second contact hole CT2. The red data line DLr may be located on one side or a side of the protrusion of the scan line SL in a +x direction. The first portion of the first active layer ACT1 is a portion of the first active layer ACT1 located in the direction to the red data line DLr with respect to the protrusion of the scan line SL.

The transistor connection line TCL is electrically connected to the second portion of the first active layer ACT1 through a third contact hole CT3 and is electrically connected to the first capacitor electrode Cst1r of the bottom metal layer BML through a fourth contact hole CT4. The second portion of the first active layer ACT1 is a portion of the first active layer ACT1 located in the direction away from the red data line DLr with respect to the protrusion of the scan line SL. A portion of the transistor connection line TCL overlapping the second active layer ACT2 may be a driving gate electrode of the first transistor T1r, which is a driving transistor.

As described above, the portion in the direction to the red data line DLr based on the portion of the second active layer ACT2 overlapping the transistor connection line TCL may serve as a second capacitor electrode. The power connection line PLCL is electrically connected, through a fifth contact hole CT5, to the portion of the active layer ACT2 located in the direction away from the red data line DLr based on the portion of the second active layer ACT2 overlapping the transistor connection line TCL. The power connection line PLCL may be electrically connected to the vertical power line PLv below the power connection line PLCL, through a sixth contact hole CT6. For reference, the horizontal power line PLh may be electrically connected to the vertical power line PLv below the horizontal power line PLh, through a seventh contact hole CT7.

The control line CL may extend substantially in the first direction (x-axis direction) and may have a protrusion protruding in the second direction (y-axis direction). The protrusion of the control line CL may serve as an initialization-sensing gate electrode of each of the third transistors T3r, T3g, and T3b, which are initialization-sensing transistors.

The initialization-sensing connection line ISCL may be electrically connected to the second active layer ACT2 below the initialization-sensing connection line ISCL through an eighth contact hole CT8, and may be electrically connected to the initialization-sensing line ISL below the initialization-sensing connection line ISCL through a ninth contact hole CT9. A portion of the second active layer ACT2 connected to the initialization-sensing connection line ISCL is a portion of the second active layer ACT2 in the direction to the initialization-sensing connection line ISCL with respect to the protrusion of the control line CL.

The shied connection line SCL may be electrically connected to the second active layer ACT2 through a tenth contact hole CT10, and may be electrically connected to the driving gate electrode shield GSr through an eleventh contact hole CT11.

The first common voltage connection line CVCL1 may be electrically connected to the vertical common voltage line CVLv below the first common voltage connection line CVCL1, through a twelfth contact hole CT12. The horizontal common voltage line CVLh may be electrically connected to the vertical common voltage line CVLv below the horizontal common voltage line CVLh, through a thirteenth contact hole CT13.

A planarization layer 106 may cover the gate layer GTL and may be disposed over the gate layer GTL. The planarization layer 106 may include an organic insulating material. For example, the planarization layer 106 may include photoresist, benzocyclobutene (BCB), polyimide, hexamethyldisiloxane (HMDSO), polymethyl methacrylate (PMMA), polystyrene, a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, or a blend thereof.

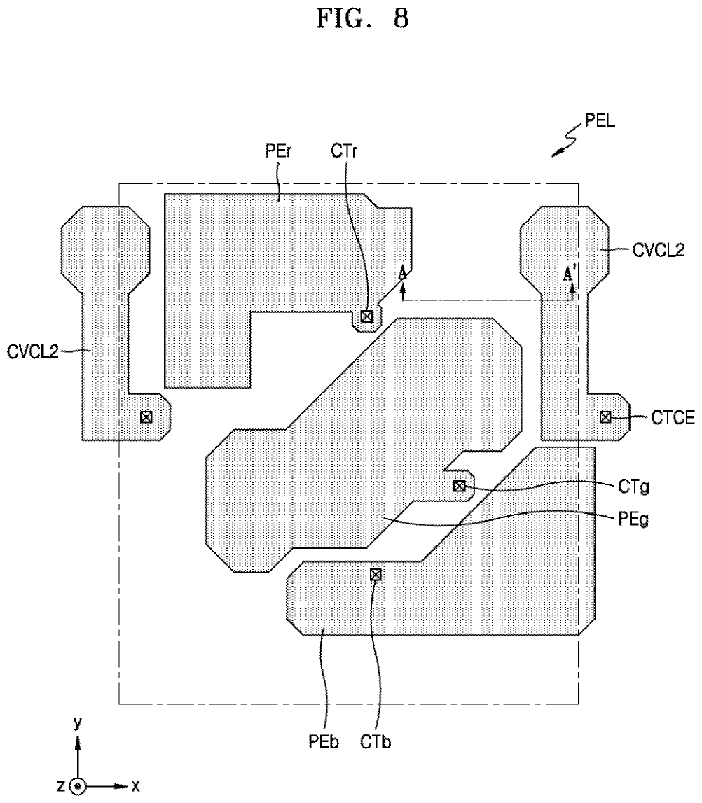

A pixel electrode layer PEL as shown in FIG. 8 may be positioned on the planarization layer 106. The pixel electrode layer PEL may include a red pixel electrode PEr, a green pixel electrode PEg, a blue pixel electrode PEb, and a second common voltage connection line CVCL2. The pixel electrode layer PEL may be a (semi) light-transmissive electrode layer or a reflective electrode layer. For example, the pixel electrode layer PEL may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer disposed over the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode layer PEL may have a three-layered structure of ITO/Ag/ITO.

A pixel defining layer 107 may be arranged on the planarization layer 106. The pixel defining layer 107 may have openings to expose respective central portions of the red pixel electrode PEr, the green pixel electrode PEg, and the blue pixel electrode PEb, and may cover respective edges of the red pixel electrode PEr, the green pixel electrode PEg, and the blue pixel electrode PEb. Accordingly, the pixel defining layer 107 may prevent an arc or the like from occurring at the respective edges of the red pixel electrode PEr, the green pixel electrode PEg, and the blue pixel electrode PEb by increasing a distance between the edge of each of the red pixel electrode PEr, the green pixel electrode PEg, and the blue pixel electrode PEb and a common electrode CE thereabove. The pixel definition layer 107 may expose at least a portion of the second common voltage connection line CVCL2 so that the common electrode CE contacts the second common voltage connection line CVCL2 to be electrically connected to the common voltage line CVL including the vertical common voltage line CVLv and the horizontal common voltage line CVLh through the first common voltage connection line CVCL1 and the second common voltage connection line CVCL2. The pixel defining layer 107 may be formed of at least one organic insulating material from among polyimide, polyamide, acryl resin, benzocyclobutene, and a phenolic resin, by using a method such as spin coating.

The common electrode CE may be a light-transmissive electrode or a reflective electrode. For example, the common electrode CE may be a transparent or semi-transparent electrode, and may include a metal thin film having a small work function, including Li, Ca, LiF, Al, Ag, Mg, or a combination thereof. The common electrode CE may further include a transparent conductive oxide (TCO) layer of, for example, ITO, IZO, ZnO, or In2O₂, disposed over the metal thin film. The common electrode CE may be formed as a single body over the entire surface of the display area DA and disposed over a plurality of pixel electrodes.

An intermediate layer may be disposed between the pixel electrodes and the common electrode CE, and at least a portion of the intermediate layer may be located within the openings defined by the pixel defining layer 107. An emission region of the organic light-emitting diode OLED may be defined by the openings. The intermediate layer may include an emission layer. The emission layer may include an organic material including a fluorescent or phosphorescent material that emits red, green, blue, or white light. The emission layer may include a low molecular organic material or a high molecular organic material, and one or more functional layers, such as a hole transport layer (HTL), a hole injection layer (HIL), an electron transport layer (ETL), and an electron injection layer (EIL), may be further arranged below and above the emission layer.

The emission layer may have a shape patterned in correspondence with each pixel electrode. Various modifications may be made to the emission layer. For example, a layer other than the emission layer included in the intermediate layer may be formed as a single body over a plurality of pixel electrodes.

A portion outlined with a one-dot dashed line in FIGS. 4 through 8 may appear repeatedly in the first direction (x-axis direction) within the display area DA of the display apparatus. Likewise, the portion outlined with the one-dot dashed line in FIGS. 4 through 8 may appear repeatedly in the second direction (y-axis direction) within the display area DA of the display apparatus. By way of example, in the second direction (y-axis direction), for example, the portion outlined by the one-dot dashed line in FIGS. 4 through 8 may appear in the case of one type of the odd-numbered rows and the even-numbered rows, and portions excluding the horizontal common voltage line CVLh and the horizontal power supply line PLv from the portion outlined by the one-dot dashed line in FIGS. 4 through 8 may appear in the case of the other rows. In other words, in case that n is an integer greater than or equal to 0, in the second direction (y-axis direction, a (2n+1)th pixel and a (2n+2)th pixel may share one horizontal common voltage line CVLh, and the (2n+2)th pixel and a (2n+3)th pixel may share one horizontal power line PLh.

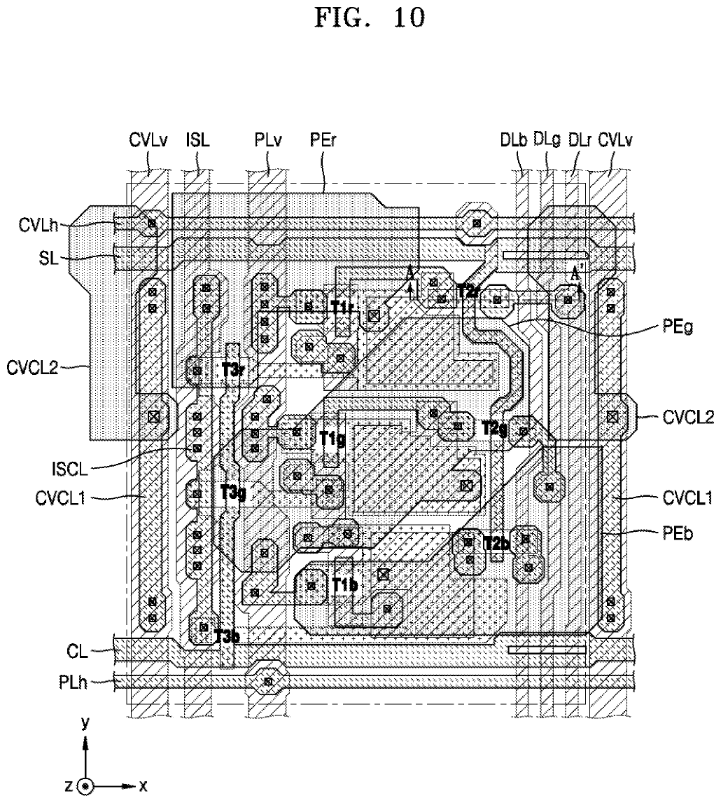

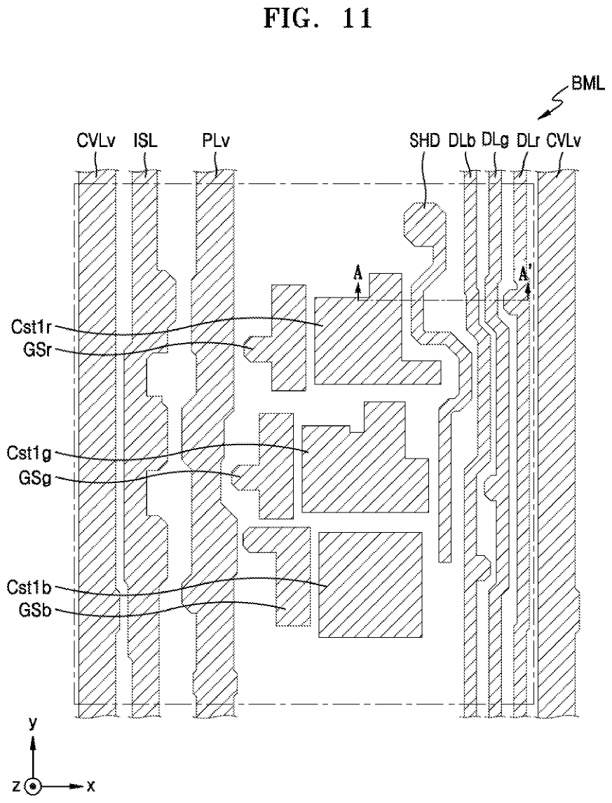

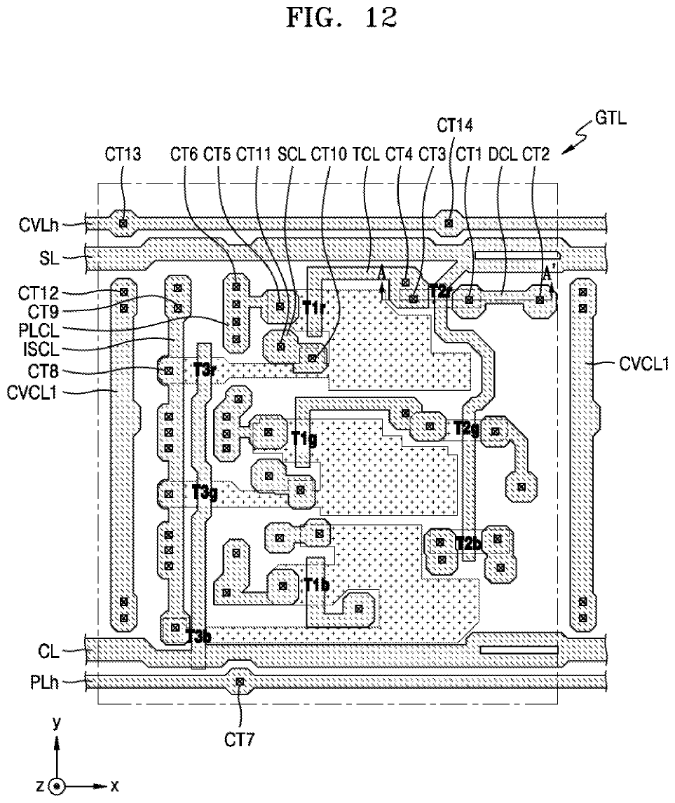

FIG. 10 is a schematic plan diagram illustrating respective locations of transistors and the storage capacitor Cst in one pixel included in the display apparatus 1 according to an embodiment, and FIGS. 11 and 12 are schematic plan diagrams illustrating, on a layer-by-layer basis, respective components of the transistors and the storage capacitor Cst of the display apparatus 1 of FIG. 10.

A difference between the display apparatus 1 according to an embodiment and the display apparatus 1 according to an embodiment described above with reference to FIG. 4 and the like is a relationship between the shield SHD and the horizontal common voltage line CVLh. As shown in FIGS. 10 through 12, in the case of the display apparatus 1 according to an embodiment, the horizontal common voltage line CVLh may be electrically connected to the shield SHD therebelow through a fourteenth contact hole CT14. As such, by electrically connecting the horizontal common voltage line CVLh, whose potential is maintained at a substantially constant common voltage ELVSS, to the shield SHD, the potential of the shield SHD may also be maintained constant. As such, by locating the shield SHD maintained at a substantially constant potential between the first portion of the first active layer ACT1 located in the direction to the red data line DLr with respect to the protrusion of the scan line SL and the second portion of the first active layer ACT1 located in a direction far from the red data line DLr with respect to the protrusion of the scan line SL, the second portion may be effectively prevented or minimized from being electrically affected by the first portion. Accordingly, a display apparatus that displays a high-quality image may be realized.

Because the portion of the scan line SL overlapping the first active layer ACT1 may be considered the gate electrode of the second transistor T2r, which is a switching transistor, the shield SHD is disposed below the gate electrode and is disposed on a side of the first active layer ACT1 such that the first active layer ACT1 is interposed between the shied SHD and the gate electrode. For reference, as described above, in case that the active layer ACT may include an oxide semiconductor, the transistors T1r, T2r, and T3r may be N-type transistors. Because the common voltage line CVL is grounded, the common voltage ELVSS may be a ground voltage that may be considered a low level. Therefore, in case that the shield SHD having the potential of the ground voltage is disposed on the side of the first active layer ACT1 such that the first active layer ACT1 is interposed between the shield SHD and the gate electrode, the second transistor T2r, which is a switching transistor, may be in a state similar to a source sync (S-Sync) in which the saturation characteristics of an N-type transistor are most advantageous.

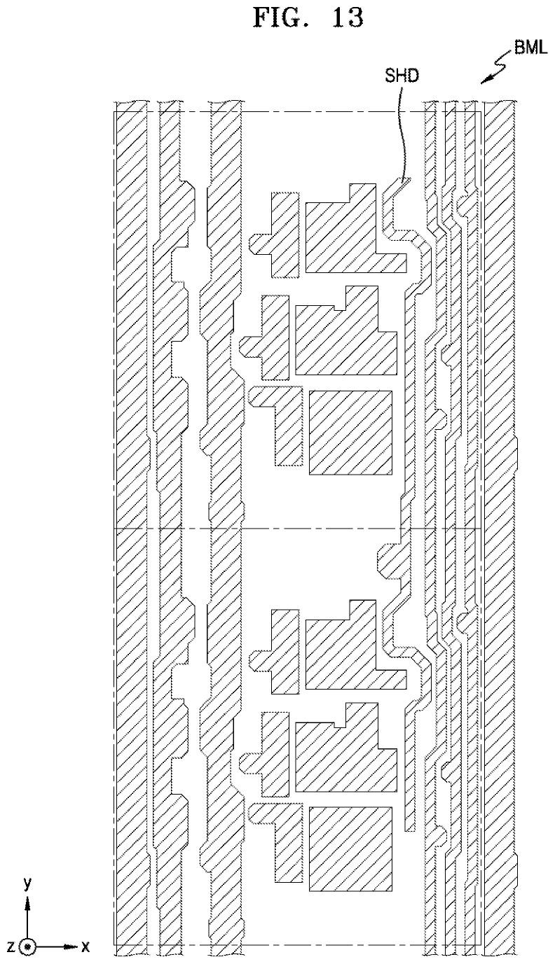

FIG. 13 is a schematic plan view illustrating one layer or a layer of the pixels included in the display apparatus 1 according to an embodiment, in detail, the bottom metal layer BML. The display apparatus 1 according to an embodiment may also have a gate layer GTL as shown in FIG. 7. A portion outlined by a one-dot dashed line in FIG. 7 may appear repeatedly in the first direction (x-axis direction) within the display area DA of the display apparatus. In the second direction (y-axis direction), for example, the portion outlined by the one-dot dashed line in FIG. 7 may appear in the case of one type of the odd-numbered rows and the even-numbered rows, and portions excluding the horizontal common voltage line CVLh and the horizontal power supply line PLv from the portion outlined by the one-dot dashed line in FIG. 7 may appear in the case of the other rows. In other words, in case that n is an integer greater than or equal to 0, in the second direction (y-axis direction), a (2n+1)th pixel and a (2n+2)th pixel may share one horizontal common voltage line CVLh, and the (2n+2)th pixel and a (2n+3)th pixel may share one horizontal power line PLh.

In order to apply the common voltage ELVSS to the shield SHD in all rows, as shown in FIG. 13, the shield SHD of a first pixel and the shield SHD of a second pixel may be a single body, wherein the first pixel and the second pixel are located adjacent to each other in the second direction (y-axis direction) with respect to the horizontal common voltage line CVLh.

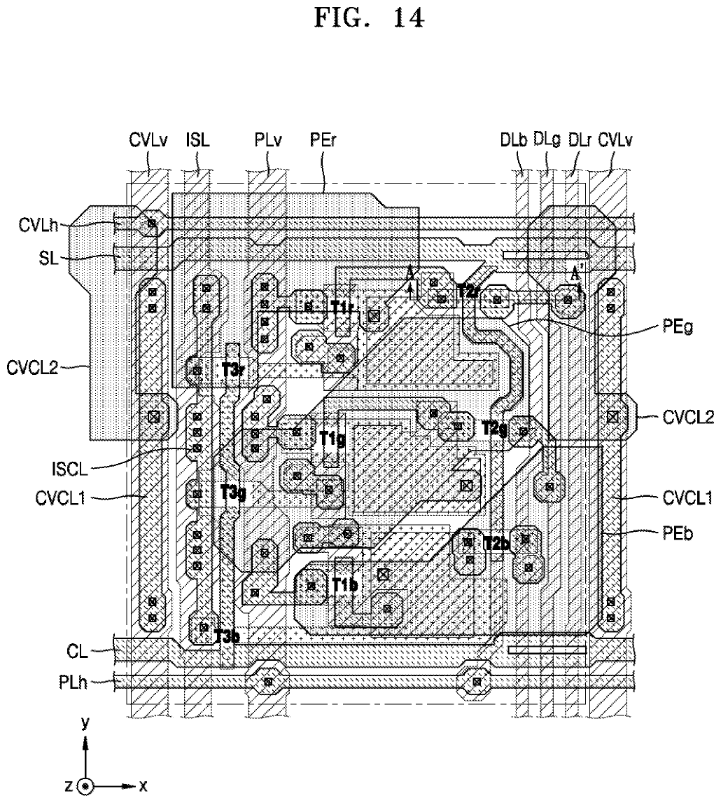

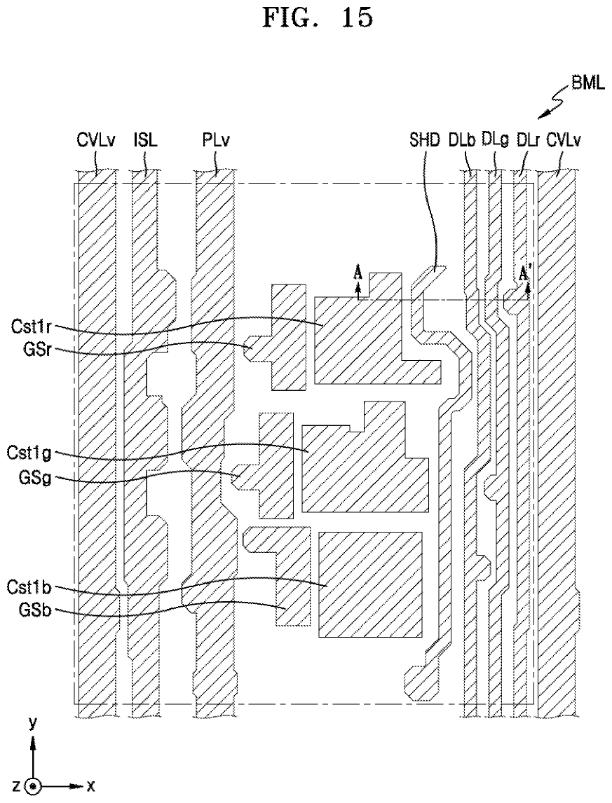

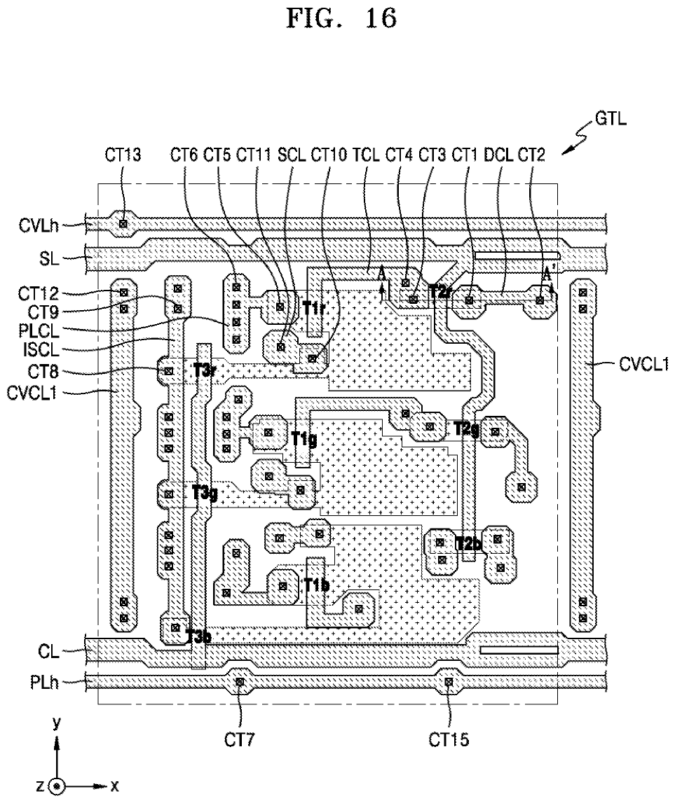

FIG. 14 is a schematic plan diagram illustrating respective locations of transistors and the storage capacitor Cst in one pixel included in the display apparatus 1 according to an embodiment, and FIGS. 15 and 16 are schematic plan diagrams illustrating, on a layer-by-layer basis, respective components of the transistors and the storage capacitor Cst of the display apparatus 1 of FIG. 14.

A difference between the display apparatus 1 according to an embodiment and the display apparatus 1 according to the embodiment described above with reference to FIG. 4 and the like is a relationship between the shield SHD and the horizontal power line PLh. As shown in FIGS. 14 through 16, in the case of the display apparatus 1 according to an embodiment, the horizontal power line PLh may be electrically connected to the shield SHD therebelow through a fifteenth contact hole CT15. As such, by electrically connecting the horizontal power line PLh, whose potential is maintained at a substantially constant power supply voltage ELVDD, to the shield SHD, the potential of the shield SHD may also be maintained constant. As such, by locating the shield SHD maintained at a substantially constant potential between the first portion of the first active layer ACT1 located in the direction to the red data line DLr with respect to the protrusion of the scan line SL and the second portion of the first active layer ACT1 located in a direction far from the red data line DLr with respect to the protrusion of the scan line SL, the second portion may be effectively prevented or minimized from being electrically affected by the first portion. Accordingly, a display apparatus that displays a high-quality image may be realized.

Because the portion of the scan line SL overlapping the first active layer ACT1 may be considered the gate electrode of the second transistor T2r, which is a switching transistor, the shield SHD is disposed below the gate electrode and is disposed on a side of the first active layer ACT1 such that the first active layer ACT1 is interposed between the shied layer SHD and the gate electrode. For reference, as described above, in case that the active layer ACT may include an oxide semiconductor, the transistors T1r, T2r, and T3r may be N-type transistors. In case that the shield SHD having the potential of the power supply voltage ELVDD of the power line PL that may be considered a high level is disposed on the side of the first active layer ACT1 such that the first active layer ACT1 is interposed between the shield layer SHD and the gate electrode, the second transistor T2r, which is a switching transistor, may be in a state similar to a gate sync (G-Sync) in which the saturation characteristics of an N-type transistor are advantageous.

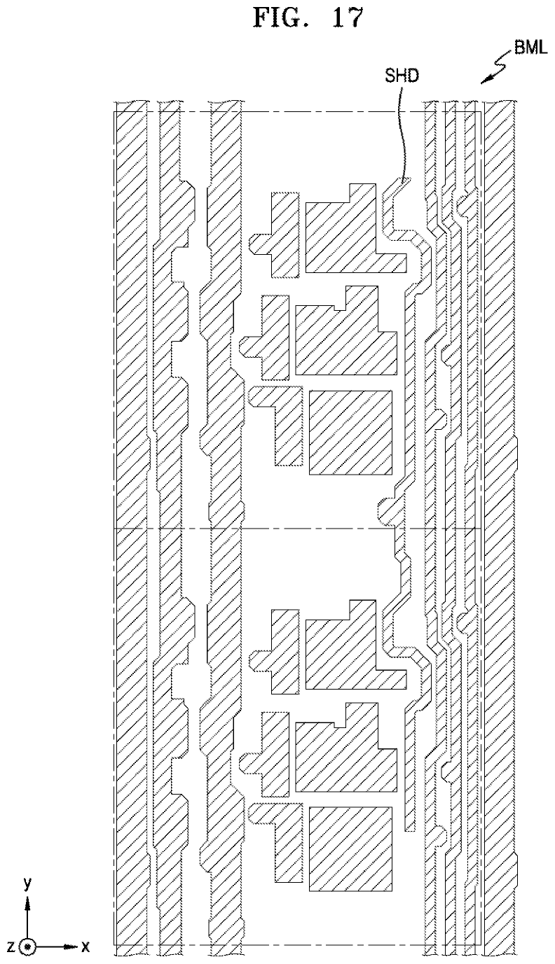

FIG. 17 is a schematic plan view illustrating one layer or a layer of the pixels included in the display apparatus 1 according to an embodiment, in detail, the bottom metal layer BML. The display apparatus 1 according to an embodiment may also have a gate layer GTL as shown in FIG. 7. A portion outlined by a one-dot dashed line in FIG. 7 may appear repeatedly in the first direction (x-axis direction) within the display area DA of the display apparatus. In the second direction (y-axis direction), for example, the portion outlined by the one-dot dashed line in FIG. 7 may appear in the case of one type of the odd-numbered rows and the even-numbered rows, and portions excluding the horizontal common voltage line CVLh and the horizontal power supply line PLv from the portion outlined by the one-dot dashed line in FIG. 7 may appear in the case of the other rows. In other words, in case that n is an integer greater than or equal to 0, in the second direction (y-axis direction), a (2n+1)th pixel and a (2n+2)th pixel may share one horizontal common voltage line CVLh, and the (2n+2)th pixel and a (2n+3)th pixel may share one horizontal power line PLh.

In order to apply the power supply voltage ELVDD to the shield SHD in all rows, as shown in FIG. 17, the shield SHD of a first pixel and the shield SHD of a second pixel may be a single body, wherein the first pixel and the second pixel are located adjacent to each other in the second direction (y-axis direction) with respect to the horizontal power line PLh.

Of course, the potential of the shield SHD may be set to be a different constant potential. For example, an initialization-sensing signal ISS of a constant potential may be applied to the shield SHD so that the shield SHD may be electrically connected to the initialization-sensing line ISL.

According to an embodiment as described above, a display apparatus capable of a high-quality image may be realized. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display apparatus comprising:
a scan line;
a data line;
a first active layer intersecting a portion of the scan line and having a first portion disposed in a direction to the data line and electrically connected to the data line; and
a shield overlapping a portion of the first active layer, the portion of the first active layer overlapping the scan line.

2. The display apparatus of claim 1, further comprising:
a data connection line electrically connecting the first portion of the first active layer to the data line.

3. The display apparatus of claim 2, wherein the scan line and the data connection line are disposed on a same layer.

4. The display apparatus of claim 1, wherein the first active layer is disposed below the scan line.

5. The display apparatus of claim 4, wherein the shield is disposed below the first active layer.

6. The display apparatus of claim 1, wherein the data line and the shield are disposed on a same layer.

7. The display apparatus of claim 1, wherein
the scan line extends in a first direction and has a protrusion protruding in a second direction intersecting the first direction, and
the first active layer extends in the first direction to intersect the protrusion of the scan line, and the first portion is disposed in a direction to the data line with respect to the protrusion of the scan line.

8. The display apparatus of claim 7, wherein the data line is disposed on a side of the protrusion of the scan line and extends in the second direction.

9. The display apparatus of claim 7, wherein the shield overlaps the protrusion of the scan line.

10. The display apparatus of claim 9, wherein the shield extends along the protrusion of the scan line.

11. The display apparatus of claim 10, wherein
the shield is disposed over a substrate, and
the protrusion of the scan line is disposed within the shield when viewed in a direction perpendicular to the substrate.

12. The display apparatus of claim 7, further comprising:
a driving gate electrode electrically connected to a second portion of the first active layer disposed in a direction away from the data line with respect to the protrusion of the scan line.

13. The display apparatus of claim 1, wherein
the scan line extends in a first direction,
the display device further comprises a horizontal common voltage line extending in the first direction, and
the shield is electrically connected to the horizontal common voltage line.

14. The display apparatus of claim 13, wherein the horizontal common voltage line and the scan line are disposed on a same layer.

15. The display apparatus of claim 13, wherein, for a first pixel and a second pixel adjacent to each other in a second direction with respect to the horizontal common voltage line, the second direction intersecting the first direction, a shield of the first pixel and a shield of the second pixel are formed as a single body.

16. The display apparatus of claim 13, further comprising:
a common electrode formed as a single body to correspond to a plurality of pixels,
wherein the common electrode is electrically connected to the horizontal common voltage line.

17. The display apparatus of claim 1, wherein
the scan line extends in a first direction,
the display device further comprises a horizontal power line extending in the first direction, and
the shield is electrically connected to the horizontal power line.

18. The display apparatus of claim 17, wherein the horizontal power line and the scan line are disposed on a same layer.

19. The display apparatus of claim 17, wherein, for a first pixel and a second pixel adjacent to each other in the second direction with respect to the horizontal power line, the second direction intersecting the first direction, a shield of the first pixel and a shield of the second pixel are formed as a single body.

20. The display apparatus of claim 17, wherein
the scan line has a protrusion protruding in a second direction intersecting the first direction, the first active layer extends in the first direction to intersect the protrusion of the scan line, and the first portion is disposed in a direction to the data line with respect to the protrusion,
the display apparatus further comprises:
a driving gate electrode electrically connected to a second portion of the first active layer disposed in a direction away from the data line with respect to the protrusion of the scan line;
a second active layer intersecting the driving gate electrode and the first active layer and the second active layer being disposed on a same layer; and
a vertical power line electrically connected to the second active layer and extending in the first direction, and
the horizontal power line is electrically connected to the vertical power line.
